(19) United States
(12) Patent Application Publication
(10) Pub. No.: US 2026/0255938 A1
(43) Pub. Date: Aug. 27, 2026

(54) Power Semiconductor Apparatus and Bonding Method Thereof

(71) Applicant: Diodes Incorporated, Plano, TX (US)

(72) Inventor: Duane Wilcoxen, Plano, TX (US)

(21) Appl. No.: 19/651,039

(22) Filed: Apr. 17, 2026

Related U.S. Application Data
(63) Continuation-in-part of application No. 19/004,306, filed on Dec. 28, 2024.
Application No. 19/004,306 is a division of application No. 18/882,721, filed on Sep. 11, 2024, now Pat. No. 12,308,337.

(51) Int. Cl. H10W 20/00; H10P 14/60; H10W 72/00; H10W 90/00

(52) U.S. Cl. CPC H10W 20/0526; H10W 20/033; H10P 14/6342; H10W 72/0198; H10W 90/734

(57) ABSTRACT

A semiconductor device includes a backside supporting layer having a first thickness, an adhesive layer over the backside supporting layer, a metal layer over the adhesive layer, wherein the metal layer functions as a backside connector and comprises a plurality of openings extending through the metal layer, a semiconductor substrate layer over the metal layer, wherein the semiconductor substrate layer has a second thickness, and wherein the adhesive layer is in direct contact with the semiconductor substrate layer through the plurality of openings, and a plurality of front side connectors, wherein active circuits in the semiconductor substrate layer are electrically coupled between the plurality of front side connectors and the metal layer.

### PRIORITY

This application is a continuation-in-part of U.S. Patent Application No. 19/004,306, filed on December 28, 2024, entitled “Power Semiconductor Apparatus and Bonding Method Thereof”, which is a divisional of U.S. Patent Application Serial No. 18/882,721, filed on September 11, 2024, now U.S. Patent No. 12,308,337, entitled “Power Semiconductor Apparatus and Bonding Method Thereof,” each of which is hereby incorporated by reference in its entirety.

### TECHNICAL FIELD

The present disclosure relates generally to the field of integrated circuits, and in particular embodiments, to techniques and mechanisms for a thin wafer power semiconductor apparatus.

### BACKGROUND

Since the invention of the integrated circuit, the semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

As semiconductor technologies evolve, thin wafer semiconductor devices emerge as an effective alternative to further reduce the physical size of semiconductor chips. For example, thin wafer semiconductor devices are increasingly vital in battery applications where space is at a premium, such as in portable electronics and electric vehicles. These devices leverage ultra-thin silicon or other semiconductor materials to minimize thickness while maintaining high electrical performance. By reducing the wafer thickness, these semiconductors can be integrated into compact battery systems, enhancing energy density without compromising functionality.

In the semiconductor fabrication process, thin wafers present significant challenges due to their instability, lack of flatness, and susceptibility to breakage and stress during processing, all of which can negatively affect device quality. Unsupported thin wafers tend to have a non-planar or wavy profile, making them unsuitable for subsequent fabrication processes that require a flat surface. Additionally, when thin wafers are unsupported during the semiconductor assembly process, they can lead to severe package warpage. This occurs because the inherent stresses in the thin wafer, coupled with the support structure, may cause uneven distribution of forces during packaging. As the wafer is processed, these stresses can become imbalanced, particularly when the wafer is released from its support or subjected to thermal cycling during assembly. This imbalance can result in the entire package bending or warping, which can affect the reliability of the final product, leading to issues such as poor electrical connections, compromised mechanical stability, and reduced overall performance of the semiconductor device. Therefore, there is a clear need for a support assembly that can accommodate thin wafers within existing processing systems. The present disclosure addresses this need.

### SUMMARY

Technical advantages are generally achieved, by embodiments of this disclosure which describe a thin wafer power semiconductor apparatus.

In accordance with an embodiment, a method comprises providing a device wafer having a first side bonded on a supporting wafer, wherein the device wafer comprises a metal layer, a semiconductor substrate, a dielectric layer and a plurality of connectors, providing a carrier, wherein a diameter of the carrier is the same as a diameter of the device wafer, coating an adhesive material onto a second side of the device wafer to form a first adhesive layer, coating the adhesive material onto the carrier to form a second adhesive layer, performing a partial curing process on the first adhesive layer and the second adhesive layer, bonding the device wafer to the carrier through bonding the first adhesive layer and the second adhesive layer together, and performing a full curing process on the adhesive material between the device wafer and the carrier.

In accordance with another embodiment, a device comprises a backside supporting layer having a first thickness, an adhesive layer over the backside supporting layer, a metal layer over the adhesive layer, wherein the metal layer functions as a backside connector, a semiconductor substrate layer over the metal layer, wherein the semiconductor substrate layer has a second thickness, and a plurality of front side connectors, wherein active circuits in the semiconductor substrate layer are electrically coupled between the plurality of front side connectors and the metal layer.

In accordance with yet another embodiment, an apparatus comprises a backside supporting layer having a first thickness; an adhesive layer over the backside supporting layer, a metal layer over the cap layer, wherein the metal layer has a second thickness, and a semiconductor substrate layer over the metal layer, wherein the semiconductor substrate layer has a third thickness, wherein the first thickness of the backside supporting layer is at least four times greater than the third thickness of the semiconductor substrate layer, and the third thickness of the semiconductor substrate layer is greater than the second thickness of the metal layer.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a perspective view of a device wafer and a carrier in accordance with various embodiments of the present disclosure;

FIG. 2 illustrates a perspective view of the device wafer and the carrier after adhesive layers are formed on these two wafers in accordance with various embodiments of the present disclosure;

FIG. 3 illustrates a perspective view of the device wafer and the carrier when a partial curing process is applied to the adhesive layers in accordance with various embodiments of the present disclosure;

FIG. 4 illustrates a perspective view of the bonding of the carrier with the device wafer in accordance with various embodiments of the present disclosure;

FIG. 5 illustrates a perspective view of the device wafer and the carrier after de-bonding the supporting wafer from the device wafer in accordance with various embodiments of the present disclosure;

FIG. 6 is a cross-sectional view of a device chip in accordance with various embodiments of the present disclosure;

FIG. 7 illustrates a flow chart of a method for bonding a device wafer to a carrier in accordance with various embodiments of the present disclosure;

FIG. 8 illustrates a cross-sectional view of a device chip based on a first implementation of a patterned metal layer in accordance with various embodiments of the present disclosure;

FIG. 9 illustrates a top view of the metal layer patterned in accordance with a first implementation of the plurality of openings in various embodiments of the present disclosure;

FIG. 10 illustrates a top view of the metal layer patterned in accordance with a second implementation of the plurality of openings in various embodiments of the present disclosure;

FIG. 11 illustrates a top view of the metal layer patterned in accordance with a third implementation of the plurality of openings in various embodiments of the present disclosure;

FIG. 12 illustrates a top view of the metal layer patterned in accordance with a fourth implementation of the plurality of openings in various embodiments of the present disclosure;

FIG. 13 illustrates a top view of the metal layer patterned in accordance with a fifth implementation of the plurality of openings in various embodiments of the present disclosure;

FIG. 14 illustrates a top view of the metal layer patterned in accordance with a sixth implementation of the plurality of openings in various embodiments of the present disclosure;

FIG. 15 illustrates a cross-sectional view of a device chip based on a second implementation of a patterned metal layer in accordance with various embodiments of the present disclosure;

FIG. 16 illustrates a top view of the metal layer shown in FIG. 15 in accordance with various embodiments of the present disclosure;

FIG. 17 illustrates a flow chart of a first method for bonding a device wafer to a backside support wafer in accordance with various embodiments of the present disclosure; and

FIG. 18 illustrates a flow chart of a second method for bonding a device wafer to a backside support wafer in accordance with various embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to embodiments in a specific context, namely a thin wafer power semiconductor apparatus. The disclosure may also be applied, however, to a variety of power devices. Hereinafter, various embodiments will be explained in detail with reference to the accompanying drawings.

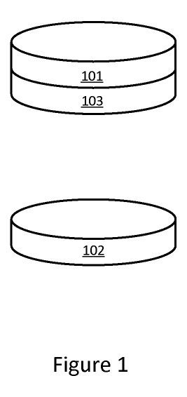

FIG. 1 illustrates a perspective view of a device wafer and a carrier in accordance with various embodiments of the present disclosure. The device wafer 101 is bonded on a supporting wafer 103. The device wafer 101 comprises a metal layer, a semiconductor substrate, a passivation layer and a plurality of connectors. In some embodiments, the passivation layer and the plurality of connectors are on a first side of the semiconductor substrate. The first side is also known as a front side of the semiconductor substrate. The metal layer is on a second side of the semiconductor substrate. The second side is also known as a backside of the semiconductor substrate. Depending on design needs and different applications, a cap layer may be formed over the metal layer. The cap layer is formed of nickel. The metal layer is formed of copper. The nickel cap layer serves as a protective layer that ensures the functionality and longevity of the copper layer. Furthermore, a plurality of dielectric layers and interconnect structures are formed between the semiconductor substrate and the passivation layer. The interconnect structures provide the necessary electrical connections between different components or regions of the device wafer 101.

In some embodiments, the semiconductor substrate has been reduced to a thickness of about 50 micrometers (µm) through suitable semiconductor thinning processes such as a chemical mechanical planarization (CMP) process, a grinding process, an etch back process, any combinations thereof. The metal layer is of a thickness of about 30 µm. The total thickness of the device wafer 101 is about 80 µm. The supporting wafer 103 has a thickness that is greater than the thickness of the device wafer 101. The supporting wafer 103 provides the necessary mechanical stability, allowing the device wafer 101 to withstand the rigors of various semiconductor processing steps.

The carrier 102 is formed of silicon. Alternatively, the carrier 102 is formed of other suitable materials such as glass. In some embodiments, a diameter of the carrier 102 is the same as a diameter of the device wafer 101. The carrier 102 is free from active devices (e.g., transistors) and passive devices (e.g., capacitors, resistors, inductors). Furthermore, the carrier 102 may also be free from conductive lines such as metal lines.

In some embodiments, the device wafer 101 includes a plurality of device chips. The device wafer 101 shown in FIG. 1 is un-sawed, and includes the semiconductor substrate. The semiconductor substrate continuously extends throughout the device wafer 101. In accordance with some embodiments, the semiconductor substrate is formed of a crystalline silicon substrate. Alternatively, the semiconductor substrate may be formed of other semiconductor materials such as silicon germanium, silicon carbon and the like.

In accordance with some embodiments, the device wafer 101 comprises a plurality of active circuits. The active circuits are vertical power devices (e.g., vertical power MOSFET, diodes). The vertical power devices are connected between the metal layer and the plurality of connectors. Alternatively, the active circuits are lateral power devices (e.g., lateral power MOSFET, diodes). The active circuits are formed at the front side of the semiconductor substrate. Furthermore, the active circuits may be logic circuits (e.g., a central processing unit (CPU), graphics processing unit (GPU), system-on-a-chip (SoC), application processor (AP), microcontroller, etc.), memory circuits (e.g., dynamic random access memory (DRAM) dies, static random access memory (SRAM) dies, etc.), power management circuits (e.g., power management integrated circuit (PMIC) dies), radio frequency (RF) circuits, sensor circuits (e.g., image sensors), micro-electro-mechanical-system (MEMS) circuits, signal processing circuits (e.g., digital signal processing (DSP) dies), any combinations thereof and the like.

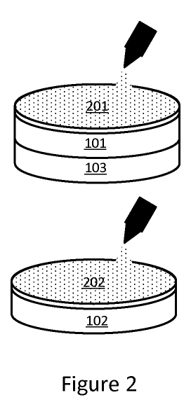

FIG. 2 illustrates a perspective view of the device wafer and the carrier after adhesive layers are formed on these two wafers in accordance with various embodiments of the present disclosure. Through a first spin coating process, an adhesive material is coated on the metal layer of the device wafer 101 to form a first adhesive layer 201. Once the first spin coating process finishes, the thickness of the first adhesive layer 201 is about 15.21 µm. Through a second spin coating process, the adhesive material is also coated on the carrier 102 to form a second adhesive layer 202. Once the second spin coating process finishes, the thickness of the second adhesive layer 202 is about 15.21 µm.

A soft bake process is applied to the first adhesive layer 201 and the second adhesive layer 202 after spin coating. The soft bake process is a thermal treatment process applied to remove residual solvent and improve the adhesion of the first adhesive layer 201 to the metal layer of the device wafer 101, and adhesion of the second adhesive layer 202 to the carrier 102. The specific conditions for the soft bake process can vary depending on design needs. In general, the soft bake process involves heating the coated device wafer and the coated carrier in an oven at a specific temperature for a set amount of time. In some embodiments, the temperature of the soft bake process is about 140 degrees. The soft bake time is about 5 minutes.

In some embodiments, the adhesive material is a polyimide adhesive material. The bonding temperature of the polyimide adhesive material is about 30 degrees. The polyimide adhesive material is in a semi-solid state when the temperature applied to the polyimide adhesive material is less than 160 degrees. The polyimide adhesive material is in a solid state after a full curing process. In some embodiments, the temperature of the full curing process is in a range from about 220 degrees to about 280 degrees. The full curing time is about 2 hours. The thickness of the adhesive layers may change after the full curing process is applied to the adhesive layers. In some embodiments, the thickness of the adhesive layers is about 15.21 µm. After the full curing process, the thickness of the adhesive layers is reduced to about 11.07 µm. The thickness shrinkage rate is about 27.26%.

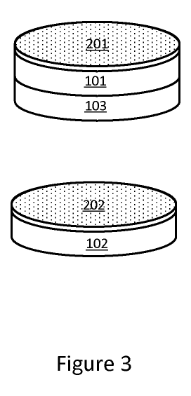

FIG. 3 illustrates a perspective view of the device wafer and the carrier when a partial curing process is applied to the adhesive layers in accordance with various embodiments of the present disclosure. The partial curing process is often used to reduce solvent and moisture content, which can enhance the adhesion and overall strength of the bond. This process typically involves applying heat to the adhesive material to drive off residual solvents and moisture. After the partial curing process, the adhesive material is in a semi-solid state. The material is subjected to higher temperatures to further reduce solvent content and eliminate moisture. This step also helps to cross-link the adhesive materials, enhancing their mechanical properties.

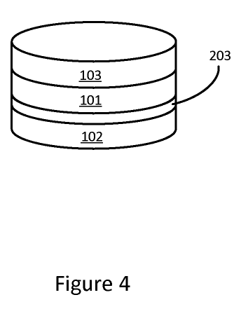

FIG. 4 illustrates a perspective view of the bonding of the carrier with the device wafer in accordance with various embodiments of the present disclosure. In the process of bonding the device wafer 101 to the carrier 102, the adhesive material is in a liquid phase at the bonding temperature.

In operation, after the device wafer is flipped, the two wafers are aligned precisely and brought into contact with each other. The adhesive material flows to fill any gaps between the surfaces, ensuring a uniform bond. The stacked wafers are placed in a vacuum chamber to remove air and prevent void formation within the bond line. Once the vacuum is established, high pressure is applied to the device wafer 101 and the carrier 102. In some embodiments, the bonding pressure is about 1 millibar. Furthermore, a bonding force of 1,000 newtons is used to press the device wafer 101 and the carrier 102 together during the bonding process. The force is applied evenly across the surfaces of the device wafer 101 and the carrier 102 to ensure that the adhesive spreads uniformly, filling any gaps between the device wafer 101 and the carrier 102 to form an adhesive layer 203. This force is essential for ensuring a strong, uniform bond between the device wafer 101 and the carrier 102.

In some embodiments, the temperature of the bonding process is about 30 degrees. The bonding time is about 4 minutes.

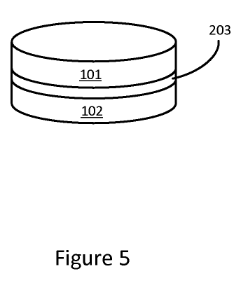

FIG. 5 illustrates a perspective view of the device wafer and the carrier after de-bonding the supporting wafer from the device wafer in accordance with various embodiments of the present disclosure. The supporting wafer 103 is de-bonded from the device wafer 101. The wafer de-bonding can be accomplished using laser-release, solvent-release or thermal-release techniques.

As shown in FIG. 5, after de-bonding the supporting wafer 103 from the device wafer 101, the carrier 102 is left in the final structure.

A full curing process is applied to the adhesive layer 203. The curing process ensures that the adhesive fully polymerizes or cross-links, transitioning from a liquid or a semi-solid state to a solid state. This reaction strengthens the bond between the device wafer 101 and the carrier 102, increasing the mechanical integrity of the final structure. In some embodiments, the temperature of the full curing process is in a range from about 260 degrees to about 280 degrees. The full curing time is about 2 hours.

After a suitable singulation process (e.g., a sawing process), the final structure including the device wafer 101, the adhesive layer 203 and the carrier 102 is divided into many individual device chips, each of which represents a complete, functional unit that can be packaged and used in electronic devices.

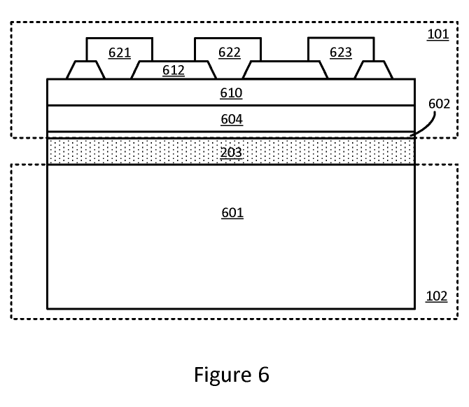

FIG. 6 is a cross-sectional view of a device chip in accordance with various embodiments of the present disclosure. The device chip comprises a backside supporting layer 601, an adhesive layer 203, a cap layer 602, a metal layer 604, the semiconductor substrate 610, a passivation layer 612 and a plurality of connectors 621, 622 and 623.

The backside supporting layer 601 shown in FIG. 6 is one piece of the carrier 102 shown in FIG. 5. As shown in FIG. 6, at a time after the singulation process has been performed, the piece of the carrier 102 is an outermost layer of a corresponding device chip.

The adhesive layer 203 is a dielectric layer formed of a polyimide adhesive material. This polyimide adhesive material has been described above with respect to FIG. 2, and hence is not discussed herein.

The cap layer 602 is formed of nickel. The cap layer serves as a protective layer that ensures the functionality and longevity of the metal layer 604.

The metal layer 604 is formed of copper. The metal layer 604 functions as a backside connector electrically connected to the active circuits in the semiconductor substrate 610. In some embodiments, the active circuits in the semiconductor substrate 610 are a plurality of diodes. The metal layer 604 is electrically connected to cathodes or anodes of the plurality of diodes. In alternative embodiments, the active circuits in the semiconductor substrate 610 are a plurality of back-to-back connected transistors. The metal layer 604 is electrically connected to shared drains or shared sources of the plurality of back-to-back connected transistors.

The semiconductor substrate 610 may be silicon, doped or undoped, or an active layer of a semiconductor-on-insulator substrate. The semiconductor substrate 610 may include other semiconductor materials, such as germanium, silicon carbide, gallium arsenic, gallium phosphide, indium phosphide, indium arsenide, and/or indium antimonide, any combinations thereof and the like.

An inter-layer dielectric (ILD) layer (not shown) may be over the active surface of the semiconductor substrate 610. The ILD layer may include one or more dielectric layers formed of materials such as Phospho-Silicate Glass (PSG), Boro-Silicate Glass (BSG), Boron-Doped Phospho-Silicate Glass (BPSG), undoped Silicate Glass (USG) or the like. The dielectric material may be deposited by spinning, chemical vapor deposition (CVD) or plasma-enhanced CVD (PECVD) techniques.

A plurality of metallization layers (not shown) may be formed over the ILD layer. The metallization layers are used to interconnect various active circuits in the semiconductor substrate 610 and further provide electrical connections between the active circuits and external circuits (not shown).

The passivation layer 612 is formed over the semiconductor substrate 610. The passivation layer 612 may be formed of one or more suitable dielectric materials such as silicon oxide, silicon nitride, low-k dielectrics such as carbon doped oxides, extremely low-k dielectrics such as porous carbon doped silicon dioxide, a polymer such as polyimide, solder resist, polybenzoxazole (PBO), a benzocyclobutene (BCB) based polymer, molding compound, any combination thereof and the like. The passivation layer 612 may be formed by spin coating, lamination, CVD, any combinations thereof and the like.

The connectors 621, 622 and 623 are formed extending through the passivation layer 612 to physically and electrically couple to the semiconductor substrate 610. Alternatively, the connectors 621, 622 and 623 may be electrically coupled to the semiconductor substrate 610 through the interconnect structures in the metallization layers. The connectors 621, 622 and 623 are formed of a conductive material such as aluminum, copper, tungsten, silver, gold, a combination thereof, and/or the like.

In some embodiments, the backside supporting layer 601 has a first thickness in a range from about 200 µm to about 725 µm. The metal layer 604 has a second thickness of about 30 µm. The semiconductor substrate 610 has a third thickness of about 50 µm.

In some embodiments, the total thickness of the device chip shown in FIG. 6 should be less than 200 µm. In order to achieve this thickness, a thinning process is performed on the backside supporting layer 601. The thinning process may be a mechanical grinding process, a chemical polishing process, an etching process or the like. By employing the thinning process, the backside supporting layer 601 can be ground so that the thickness of the backside supporting layer 601 may be reduced from about 725 µm to about 200 µm.

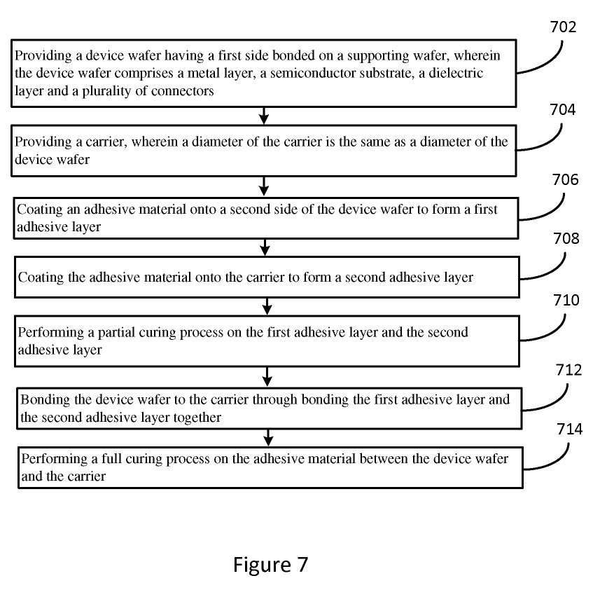

FIG. 7 illustrates a flow chart of a method for bonding a device wafer to a carrier in accordance with various embodiments of the present disclosure. This flowchart shown in FIG. 7 is merely an example, which should not unduly limit the scope of the claims. One of ordinary skill in the art would recognize many variations, alternatives, and modifications. For example, various steps illustrated in FIG. 7 may be added, removed, replaced, rearranged and repeated.

At step 702, a device wafer is provided. The device wafer has a first side bonded on a supporting wafer. The device wafer comprises a metal layer, a semiconductor substrate, a dielectric layer and a plurality of connectors.

At step 704, a carrier is provided. A diameter of the carrier is the same as a diameter of the device wafer.

At step 706, an adhesive material is coated onto a second side of the device wafer to form a first adhesive layer.

At step 708, the adhesive material is coated onto the carrier to form a second adhesive layer.

At step 710, a partial curing process is performed on the first adhesive layer and the second adhesive layer.

At step 712, the device wafer is bonded to the carrier.

At step 714, a full curing process is performed on the adhesive material between the device wafer and the carrier.

The method further comprises after bonding the device wafer to the carrier wafer and before performing the full curing process on the adhesive material, de-bonding the supporting wafer from the device wafer.

The method further comprises after performing the full curing process on the adhesive material, performing a singulation process to separate a plurality of chips in the device wafer into a plurality of packages, wherein each of the plurality of packages comprises a piece of the carrier.

At a time after the singulation process has been performed, the piece of the carrier is an outermost layer of a corresponding package.

The method further comprises at a first temperature, performing the partial curing process on the adhesive material over the second side of the device wafer and the carrier, at a second temperature, bonding the device wafer to the carrier, and at a third temperature, performing the full curing process on the adhesive material, wherein the third temperature is at least 100 degrees higher than the first temperature, and the first temperature is at least 100 degrees higher than the second temperature.

The first temperature is about 140 degrees, the second temperature is about 30 degrees, and the third temperature is about 260 degrees.

Before performing the full curing process on the adhesive material, an adhesive layer between the device wafer and the carrier has a first thickness. After performing the full curing process on the adhesive material, the adhesive layer between the device wafer and the carrier has a second thickness. The metal layer has a third thickness, and wherein the first thickness is greater than the third thickness, and the third thickness is greater than the second thickness.

The adhesive material is a polyimide adhesive material.

The metal layer is in direct contact with the semiconductor substrate, and the metal layer functions as a connector electrically coupled to active circuits in the semiconductor substrate.

The method further comprises bonding the device wafer to the carrier using liquid-phase bonding under high pressure in a vacuum.

In some embodiments, the metal layer formed over the semiconductor substrate is patterned to include a plurality of openings extending through the metal layer. The plurality of openings may be formed using a photolithography and etching process or a patterned electroplating process. The openings are distributed across the metal layer in a predetermined pattern, such as an array arranged in rows and columns, although other distributions may also be used. Through these openings, portions of an adhesive layer subsequently formed over the metal layer are brought into direct contact with the underlying semiconductor substrate. This configuration enhances bonding strength between the semiconductor substrate and a backside support wafer by allowing the adhesive material to directly adhere to the semiconductor substrate in addition to the metal layer.

In some embodiments, the patterning of the metal layer further includes forming metal-free regions corresponding to dicing lanes of the device wafer. The dicing lanes define regions along which the device wafer is separated into individual chips during a singulation process. By removing the metal layer from regions corresponding to the dicing lanes, mechanical stress and chipping associated with the presence of a relatively thick metal layer during dicing can be reduced. In addition, edge regions of the semiconductor substrate may be exposed by recessing the metal layer from the outer edge of the semiconductor substrate, thereby allowing the adhesive layer to directly contact the semiconductor substrate in these regions. These features improve mechanical integrity and yield during singulation while maintaining sufficient metal coverage for electrical conduction.

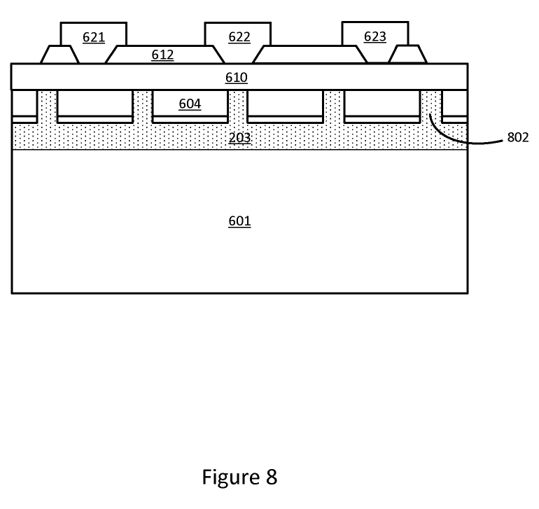

FIG. 8 illustrates a cross-sectional view of a device chip based on a first implementation of a patterned metal layer in accordance with various embodiments of the present disclosure. The device chip shown in FIG. 8 is similar to the device chip shown in FIG. 6, and like reference numerals refer to like elements, which are not repeated herein for brevity. In contrast to the embodiment shown in FIG. 6, the metal layer 604 in FIG. 8 comprises a plurality of openings 802 extending through the metal layer 604.

In some embodiments, the plurality of openings 802 is formed during fabrication of the metal layer 604. For example, a photoresist patterning process may be employed during an electroplating process of the metal layer 604 to define the locations of the openings 802. More specifically, a patterned photoresist layer is formed over the semiconductor substrate at selected regions where the openings 802 are to be formed. The metal layer 604 is then electroplated in regions not covered by the photoresist, thereby forming the metal layer 604 with the plurality of openings 802 extending through the metal layer 604. After the electroplating process, the photoresist is removed, leaving the patterned metal layer 604 with the openings 802. In alternative embodiments, other suitable fabrication techniques, such as photolithography followed by etching or patterned deposition processes, may also be used to form the openings 802.

In the fabrication process, through these openings, portions of the adhesive layer 203 are in direct contact with the semiconductor substrate 610. This direct contact configuration allows the adhesive layer 203 to adhere directly to the semiconductor substrate 610 in addition to the metal layer 604, thereby improving bonding strength between the semiconductor substrate 610 and the backside supporting layer 601. It should be noted that the backside support wafer may be referred to as a backside supporting layer after singulation.

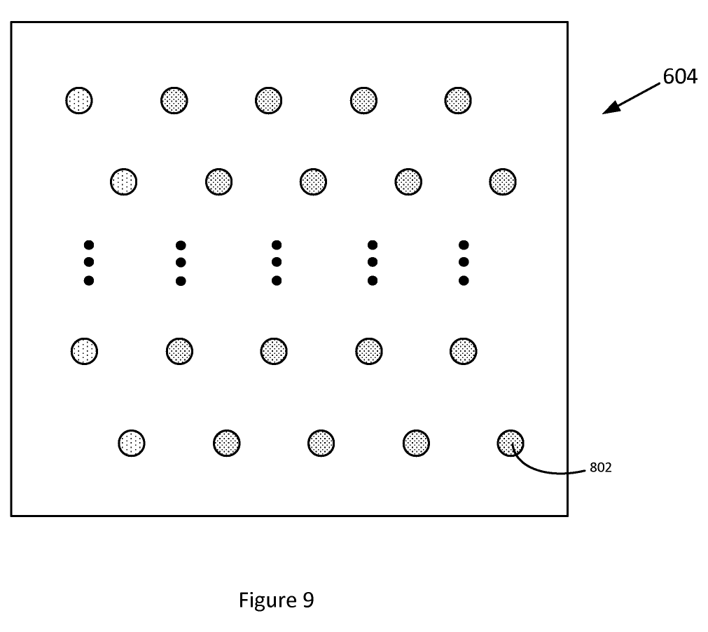

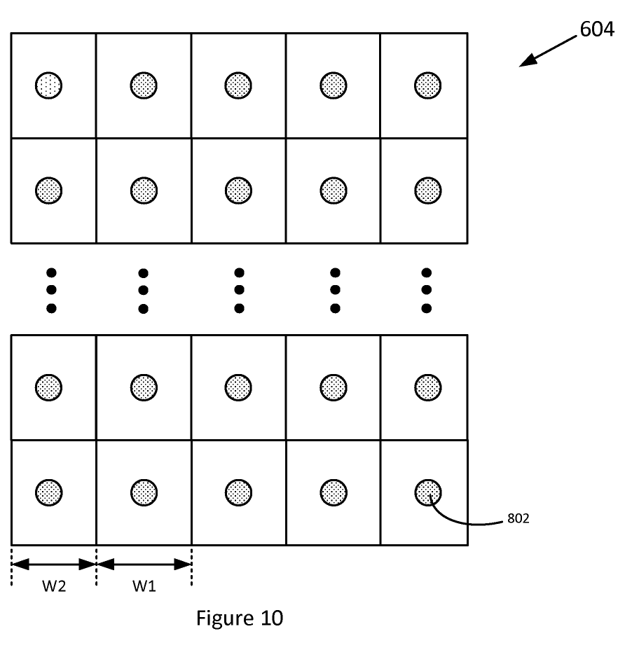

In some embodiments, the plurality of openings 802 is randomly distributed across the metal layer 604 (e.g., the opening configuration shown in FIG. 9). In alternative embodiments, the plurality of openings 802 is distributed across the metal layer 604 in a predetermined pattern (e.g., the opening configurations shown in FIGS. 10-14). The size, shape, and distribution of the openings may be selected based on design considerations, including bonding strength and electrical conduction requirements. The metal layer 604 remains continuous to provide a conductive path for electrical coupling to active circuits within the semiconductor substrate 610, while the openings provide localized regions for enhanced adhesion. This combined structure improves mechanical reliability of the bonded structure while maintaining desired electrical performance.

FIG. 9 illustrates a top view of the metal layer patterned in accordance with a first implementation of the plurality of openings in various embodiments of the present disclosure. As shown in FIG. 9, the metal layer 604 comprises a plurality of openings 802 distributed across the metal layer 604. In this implementation, the plurality of openings 802 is arranged in a non-uniform or random distribution in the metal layer 604. The plurality of openings 802 is not arranged in a regular array or periodic pattern.

In FIG. 9, the dotted regions within the openings 802 represent portions of the adhesive material filling the openings 802. Accordingly, through the openings 802, portions of the adhesive layer 203 are brought into direct contact with the semiconductor substrate 610, thereby improving the bonding strength between the semiconductor substrate 610 and the backside support structure.

The distribution and density of the plurality of openings 802 may be selected to achieve a balance between bonding strength and electrical conductivity. On one hand, increasing the number and/or total area of the openings 802 allows a greater portion of the adhesive layer to be in direct contact with the semiconductor substrate 610, thereby improving adhesion strength between the semiconductor substrate 610 and the backside support structure. On the other hand, reducing the number and/or total area of the openings 802 preserves a larger continuous area of the metal layer 604, which enhances electrical conductivity and reduces resistive losses. Accordingly, the pattern, size, and density of the plurality of openings 802 may be optimized based on specific design requirements and performance considerations.

It should be noted that the arrangement of the plurality of openings 802 shown in FIG. 9 is merely an example for illustrative purposes. Various modifications and alternative distributions of the openings 802 may be employed, including different random distributions, semi-random distributions, or other non-uniform patterns, without departing from the scope of the present disclosure.

FIG. 10 illustrates a top view of the metal layer patterned in accordance with a second implementation of the plurality of openings in various embodiments of the present disclosure. As shown in FIG. 10, the metal layer 604 is divided into a plurality of regions arranged in rows and columns. Each of the regions includes an opening 802 located at or near a central portion of the respective region. The openings extend through the metal layer 604, allowing an adhesive layer (e.g., adhesive layer 203 shown in FIG. 8) to be in direct contact with a semiconductor substrate (e.g., semiconductor substrate 610 shown in FIG. 8) through the openings.

In some embodiments, during a singulation process, dicing lanes may pass through portions of the regions of the metal layer 604. After dicing, the regions intersected by the dicing lanes become edge regions of individual device chips as shown in FIG. 10. As a result, widths (e.g., W2) of these edge regions may be smaller than widths (e.g., W1) of regions located away from the edges (e.g., regions in middle columns). This configuration maintains sufficient metal coverage for electrical conduction.

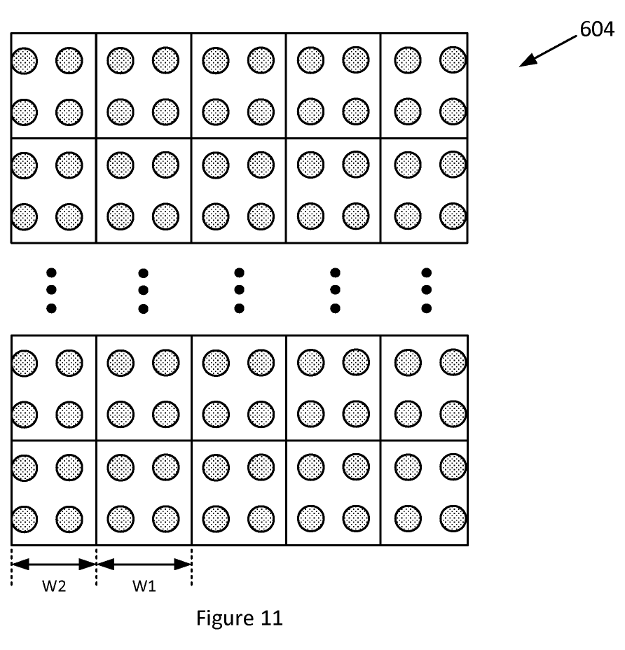

FIG. 11 illustrates a top view of the metal layer patterned in accordance with a third implementation of the plurality of openings in various embodiments of the present disclosure. As shown in FIG. 11, the metal layer 604 is divided into a plurality of regions arranged in rows and columns. In this implementation, each region includes four openings extending through the metal layer 604. The four openings are arranged symmetrically within the region, for example at or near four corner portions of the respective region as shown in FIG. 11. Through these openings, an adhesive layer (e.g., adhesive layer 203 shown in FIG. 8) may be in direct contact with a semiconductor substrate (e.g., semiconductor substrate 610 shown in FIG. 8), thereby enhancing bonding strength.

In some embodiments, the symmetric arrangement of the four openings within each region provides a balanced distribution of adhesion points while maintaining sufficient metal continuity for electrical conduction. Similar to the embodiment described with respect to FIG. 10, regions located near edges of the metal layer 604 may correspond to dicing lane locations, and widths of such edge regions may be smaller than widths of interior regions.

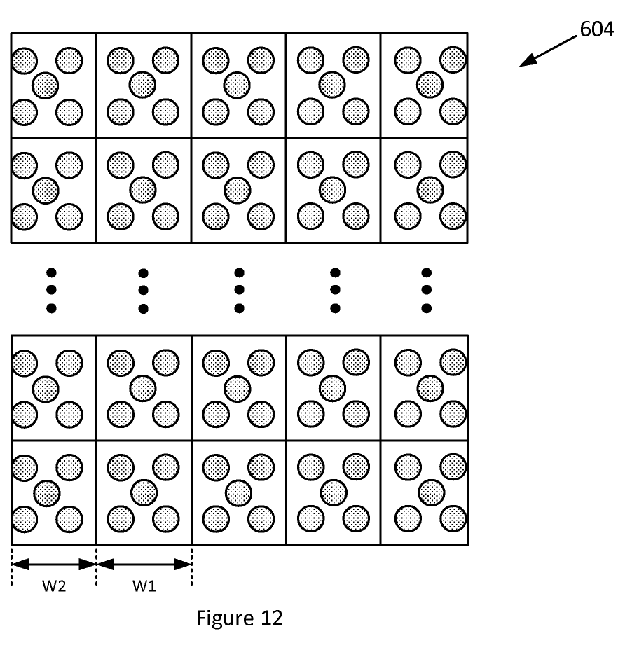

FIG. 12 illustrates a top view of the metal layer patterned in accordance with a fourth implementation of the plurality of openings in various embodiments of the present disclosure. As shown in FIG. 12, the metal layer 604 is divided into a plurality of regions arranged in rows and columns. In this implementation, each region includes five openings extending through the metal layer 604, including a center opening located at or near a central portion of the region and four additional openings distributed within the region.

In some embodiments, the center opening and two of the four openings are aligned along a first diagonal of the region. The center opening and the other two openings are aligned along a second diagonal of the region. This configuration provides a symmetric distribution of openings within each region, thereby enhancing adhesion between an adhesive layer (e.g., adhesive layer 203 shown in FIG. 8) and a semiconductor substrate (e.g., semiconductor substrate 610 shown in FIG. 8). Similar to the embodiments described above, regions near edges of the metal layer 604 may correspond to dicing lane locations and may have reduced widths relative to interior regions.

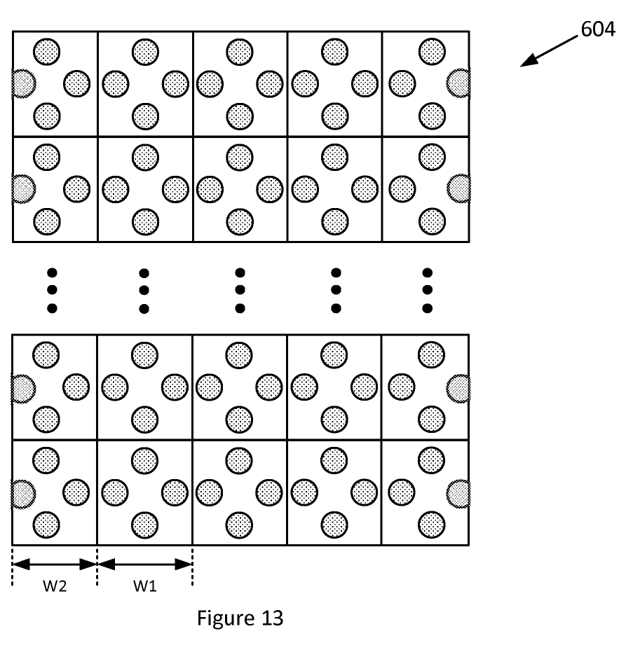

FIG. 13 illustrates a top view of the metal layer patterned in accordance with a fifth implementation of the plurality of openings in various embodiments of the present disclosure. As shown in FIG. 13, the metal layer 604 is divided into a plurality of regions arranged in rows and columns. In this implementation, each region includes four openings extending through the metal layer 604. The four openings are positioned at or near midpoints of respective sides of the region as shown in FIG. 13.

In some embodiments, the placement of the openings at the midpoints of the region provides a balanced distribution of adhesion points along lateral directions, thereby enhancing bonding between an adhesive layer (e.g., adhesive layer 203 shown in FIG. 8) and a semiconductor substrate (e.g., semiconductor substrate 610 shown in FIG. 8). Similar to the embodiments described above, regions near edges of the metal layer 604 may correspond to dicing lane locations and may have reduced widths relative to interior regions. Furthermore, openings located in edge regions may be partially intersected by dicing lanes. As a result, after the dicing process is completed, only portions of such openings remain, as illustrated in FIG. 13.

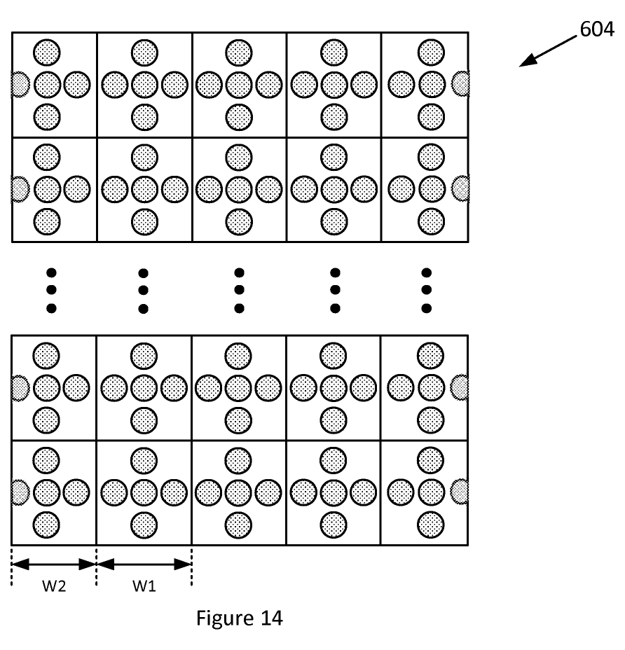

FIG. 14 illustrates a top view of the metal layer patterned in accordance with a sixth implementation of the plurality of openings in various embodiments of the present disclosure. As shown in FIG. 14, the metal layer 604 is divided into a plurality of regions arranged in rows and columns. In this implementation, each region includes five openings extending through the metal layer 604, including a center opening located at or near a central portion of the region and four additional openings distributed within the region as shown in FIG. 14.

In some embodiments, the center opening and two of the four openings are aligned along a first direction passing through the center of the region. The center opening and the other two openings are aligned along a second direction passing through the center of the region. The second direction is orthogonal to the first direction. This configuration provides a balanced distribution of openings in both lateral directions, thereby enhancing adhesion between an adhesive layer (e.g., adhesive layer 203 shown in FIG. 8) and a semiconductor substrate (e.g., semiconductor substrate 610 shown in FIG. 8). Similar to the embodiments described above, regions near edges of the metal layer 604 may correspond to dicing lane locations and may have reduced widths relative to interior regions.

In some embodiments, although the openings 802 illustrated in FIGS. 9-14 are shown as having a circular shape, the openings 802 are not limited to circular geometries. Depending on design requirements and fabrication considerations, the openings 802 may have other shapes, such as square, rectangular, oval, polygonal, irregular shapes, any combinations thereof and the like. The shape of the openings 802 may be selected to optimize parameters such as adhesion strength, stress distribution, and electrical conductivity. Accordingly, various alternative shapes and geometries of the openings 802 may be employed without departing from the scope of the present disclosure.

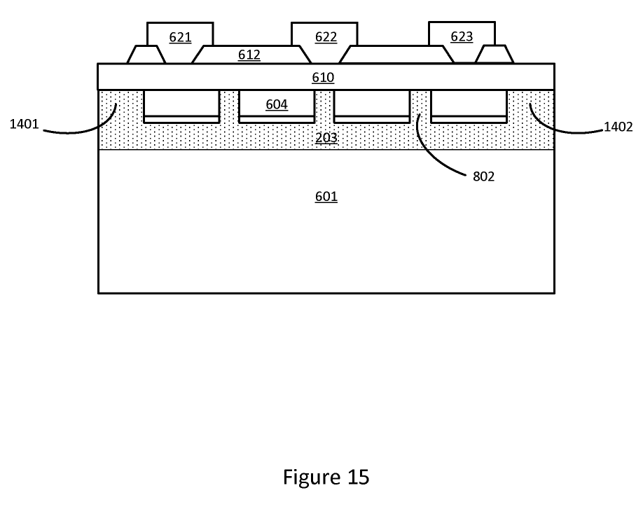

FIG. 15 illustrates a cross-sectional view of a device chip based on a second implementation of a patterned metal layer in accordance with various embodiments of the present disclosure. The device chip shown in FIG. 15 is similar to the device chip shown in FIG. 8, and like reference numerals refer to like elements, which are not repeated herein for brevity. In contrast to the embodiment shown in FIG. 8, the metal layer 604 in FIG. 15 is patterned with consideration of dicing lane locations of a device wafer.

In some embodiments, portions of the metal layer 604 corresponding to dicing lanes are removed such that the metal layer 604 is recessed from regions 1401 and 1402 where singulation occurs. As a result, the adhesive layer 203 may be in direct contact with the semiconductor substrate 610 in regions 1401 and 1402 corresponding to the dicing lanes. This configuration reduces mechanical stress and chipping associated with the presence of the metal layer during dicing, thereby improving singulation reliability and yield. At the same time, the metal layer 604 remains sufficiently continuous in non-dicing regions to provide electrical conduction and structural support.

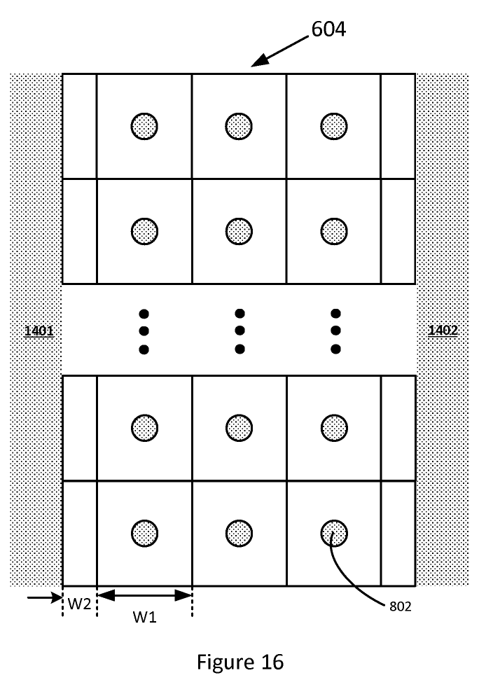

FIG. 16 illustrates a top view of the metal layer shown in FIG. 15 in accordance with various embodiments of the present disclosure. As shown in FIG. 16, the metal layer 604 includes a plurality of openings distributed across the metal layer 604. In some embodiments, the openings are arranged in a plurality of regions corresponding to a layout of device chips within a device wafer. Regions 1401 and 1402 corresponding to dicing lanes are metal-free portions, while regions away from the dicing lanes include openings configured to allow the adhesive layer to be in direct contact with the semiconductor substrate.

As shown in FIG. 16, each of the regions in middle columns includes an opening 802 located at or near a central portion of the respective region. The openings extend through the metal layer 604, allowing an adhesive layer (e.g., adhesive layer 203 shown in FIG. 15) to be in direct contact with a semiconductor substrate (e.g., semiconductor substrate 610 shown in FIG. 15) through the openings.

As indicated by regions 1401 and 1402, the metal layer 604 is recessed from an outer edge of the semiconductor substrate. Due to this recess, portions of the edge regions have been removed. As a result, the widths (e.g., W2) of the edge regions are smaller than widths (e.g., W1) of regions located away from the edges (e.g., regions in middle columns) as shown in FIG. 16.

In some embodiments, the openings within each region of FIG. 16 may be arranged in any suitable pattern, such as patterns described with respect to FIGS. 9 through 14. For example, the openings may be arranged as a single center opening, a plurality of openings symmetrically arranged within a region, or a combination of a center opening and additional openings aligned along diagonal or orthogonal directions. It should be appreciated that the specific arrangement of openings may be varied depending on design requirements, and other opening implementations may also be applied without departing from the scope of the present disclosure.

In some embodiments, the plurality of openings 802 and the recessed metal regions corresponding to dicing lanes are implemented together as shown in FIG. 16, such that adhesion is enhanced in interior regions while stress concentration during singulation is reduced at edge regions, thereby improving both bonding strength and dicing reliability.

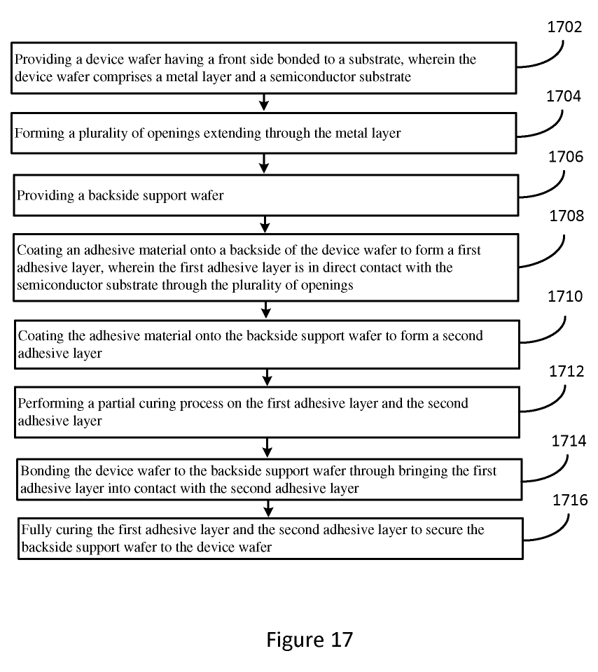

FIG. 17 illustrates a flow chart of a first method for bonding a device wafer to a backside support wafer in accordance with various embodiments of the present disclosure. This flowchart shown in FIG. 17 is merely an example, which should not unduly limit the scope of the claims. One of ordinary skill in the art would recognize many variations, alternatives, and modifications. For example, various steps illustrated in FIG. 17 may be added, removed, replaced, rearranged and repeated.

At step 1702, a device wafer is provided. The device wafer has a front side bonded to a substrate, wherein the device wafer comprises a metal layer and a semiconductor substrate. It should be noted that the supporting wafer 103 may be alternatively referred to as a substate.

At step 1704, a plurality of openings is formed, the openings extending through the metal layer.

At step 1706, a backside support wafer is provided.

At step 1708, an adhesive material is coated onto a backside of the device wafer to form a first adhesive layer, wherein the first adhesive layer is in direct contact with the semiconductor substrate through the plurality of openings.

At step 1710, the adhesive material is coated onto the backside support wafer to form a second adhesive layer.

At step 1712, a partial curing process is performed on the first adhesive layer and the second adhesive layer.

At step 1714, the device wafer is bonded to the backside support wafer through bringing the first adhesive layer into contact with the second adhesive layer.

At step 1716, the first adhesive layer and the second adhesive layer are fully cured to secure the backside support wafer to the device wafer.

The method further comprises after bonding the device wafer to the backside support wafer and before performing the full curing process on the adhesive material, de-bonding the substrate from the device wafer, and after performing the full curing process on the adhesive material, performing a singulation process to separate a plurality of chips in the device wafer into a plurality of packages, wherein each of the plurality of packages comprises a piece of the backside support wafer.

The method further comprises patterning the metal layer to define metal-free regions aligned with saw dicing lanes of the semiconductor substrate.

The method further comprises forming the plurality of openings in a plurality of regions arranged in rows and columns, wherein for openings formed in regions in middle columns, each opening is located at a center portion of a corresponding region.

The method further comprises forming the plurality of openings in a plurality of regions arranged in rows and columns, wherein for regions in middle columns, each region comprises four openings symmetrically arranged within the region.

The method further comprises forming a center opening at a central portion of the region, and patterning the metal layer such that the center opening and two of the four openings are aligned along a first diagonal of the region, and the center opening and the other two of the four openings are aligned along a second diagonal of the region.

The method further comprises forming a center opening at a central portion of the region, and patterning the metal layer such that the center opening and two of the four openings are aligned along a first direction through the center of the region, and the center opening and the other two of the four openings are aligned along a second direction through the center of the region, wherein the second direction is orthogonal to the first direction.

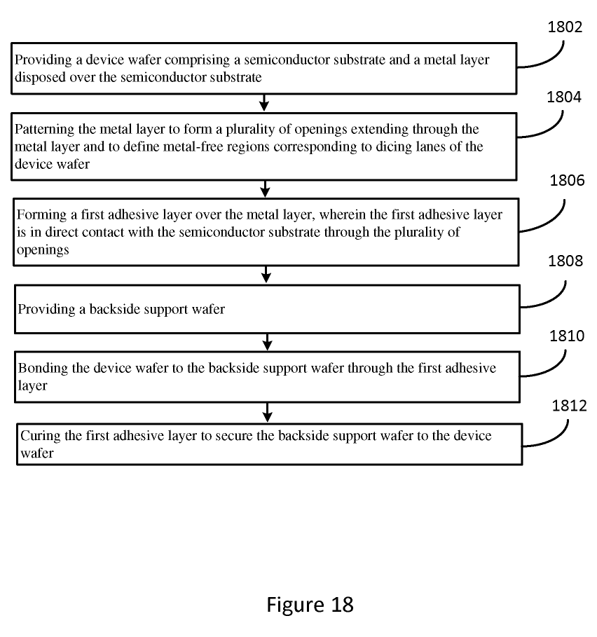

FIG. 18 illustrates a flow chart of a second method for bonding a device wafer to a backside support wafer in accordance with various embodiments of the present disclosure. This flowchart shown in FIG. 18 is merely an example, which should not unduly limit the scope of the claims. One of ordinary skill in the art would recognize many variations, alternatives, and modifications. For example, various steps illustrated in FIG. 18 may be added, removed, replaced, rearranged and repeated.

At step 1802, a device wafer is provided. The device wafer comprises a semiconductor substrate and a metal layer disposed over the semiconductor substrate.

At step 1804, the metal layer is patterned to form a plurality of openings extending through the metal layer and to define metal-free regions corresponding to dicing lanes of the device wafer.

At step 1806, a first adhesive layer is formed over the metal layer, wherein the first adhesive layer is in direct contact with the semiconductor substrate through the plurality of openings.

At step 1808, a backside support wafer is provided.

At step 1810, the device wafer is bonded to the backside support wafer through the first adhesive layer.

At step 1812, the first adhesive layer is cured to secure the backside support wafer to the device wafer.

The method further comprises forming a second adhesive layer over the backside support wafer, wherein bonding the device wafer to the backside support wafer comprises bringing the first adhesive layer into contact with the second adhesive layer, and curing the first adhesive layer and the second adhesive layer to secure the backside support wafer to the device wafer.

The method further comprises after curing the adhesive layer to secure the backside support wafer to the device wafer, performing a singulation process to separate a plurality of chips in the device wafer into a plurality of packages, wherein each of the plurality of packages comprises a piece of the backside support wafer.

In some embodiments, the metal layer is recessed from an outer edge of the semiconductor substrate to define an exposed edge portion of the semiconductor substrate, and wherein the exposed edge portion of the semiconductor substrate is in direct contact with the first adhesive layer.

In accordance with an embodiment, a semiconductor device comprises a backside supporting layer having a first thickness, an adhesive layer over the backside supporting layer, a metal layer over the adhesive layer, wherein the metal layer functions as a backside connector and comprises a plurality of openings extending through the metal layer, a semiconductor substrate layer over the metal layer, wherein the semiconductor substrate layer has a second thickness, and wherein the adhesive layer is in direct contact with the semiconductor substrate layer through the plurality of openings, and a plurality of front side connectors, wherein active circuits in the semiconductor substrate layer are electrically coupled between the plurality of front side connectors and the metal layer.

Optionally, in the preceding aspect, the backside supporting layer is formed of silicon, and wherein the backside supporting layer is free from the active devices, and the adhesive layer is a dielectric layer formed of a polyimide adhesive material.

Optionally, in any of the preceding aspects, the semiconductor device further comprises a cap layer formed between the adhesive layer and metal layer, and a passivation layer over the semiconductor substrate layer.

Optionally, in any of the preceding aspects, the first thickness of the backside supporting layer is greater than the second thickness of the semiconductor substrate layer.

Optionally, in any of the preceding aspects, the metal layer comprises a plurality of regions arranged in rows and columns, and wherein for openings formed in regions in middle columns, each opening is located at a center portion of a corresponding region.

Optionally, in any of the preceding aspects, the metal layer comprises a plurality of regions arranged in rows and columns, and wherein for regions in middle columns, each region comprises four openings symmetrically arranged within the region.

Optionally, in any of the preceding aspects, each region further comprises a center opening located at a central portion of the region, the center opening and two of the four openings are aligned along a first diagonal of the region, and the center opening and the other two of the four openings are aligned along a second diagonal of the region.

Optionally, in any of the preceding aspects, each region further comprises a center opening located at a central portion of the region, the center opening and two of the four openings are aligned along a first direction through a center of the region, and the center opening and the other two of the four openings are aligned along a second direction through the center of the region, the second direction being orthogonal to the first direction.

Optionally, in any of the preceding aspects, the metal layer is recessed from an outer edge of the semiconductor substrate layer such that an edge portion of the semiconductor substrate layer is in direct contact with the adhesive layer.

In accordance with another embodiment, a method comprises providing a device wafer having a front side bonded to a substrate, wherein the device wafer comprises a metal layer and a semiconductor substrate, forming a plurality of openings extending through the metal layer, providing a backside support wafer, coating an adhesive material onto a backside of the device wafer to form a first adhesive layer, wherein the first adhesive layer is in direct contact with the semiconductor substrate through the plurality of openings, coating the adhesive material onto the backside support wafer to form a second adhesive layer, performing a partial curing process on the first adhesive layer and the second adhesive layer, bonding the device wafer to the backside support wafer through bringing the first adhesive layer into contact with the second adhesive layer, and fully curing the first adhesive layer and the second adhesive layer to secure the backside support wafer to the device wafer.

Optionally, in the preceding aspect, the method further comprises after bonding the device wafer to the backside support wafer and before performing the full curing process on the adhesive material, de-bonding the substrate from the device wafer, and after performing the full curing process on the adhesive material, performing a singulation process to separate a plurality of chips in the device wafer into a plurality of packages, wherein each of the plurality of packages comprises a piece of the backside support wafer.

Optionally, in any of the preceding aspects, the method further comprises patterning the metal layer to define metal-free regions aligned with saw dicing lanes of the semiconductor substrate.

Optionally, in any of the preceding aspects, the method further comprises forming the plurality of openings in a plurality of regions arranged in rows and columns, wherein for openings formed in regions in middle columns, each opening is located at a center portion of a corresponding region.

Optionally, in any of the preceding aspects, the method further comprises forming the plurality of openings in a plurality of regions arranged in rows and columns, wherein regions in middle columns, each region comprises four openings symmetrically arranged within the region.

Optionally, in any of the preceding aspects, the method further comprises forming a center opening at a central portion of the region, and patterning the metal layer such that the center opening and two of the four openings are aligned along a first diagonal of the region, and the center opening and the other two of the four openings are aligned along a second diagonal of the region.

Optionally, in any of the preceding aspects, the method further comprises forming a center opening at a central portion of the region, and patterning the metal layer such that the center opening and two of the four openings are aligned along a first direction through the center of the region, and the center opening and the other two of the four openings are aligned along a second direction through the center of the region, wherein the second direction is orthogonal to the first direction.

In accordance with yet another embodiment, a method comprises providing a device wafer comprising a semiconductor substrate and a metal layer disposed over the semiconductor substrate, patterning the metal layer to form a plurality of openings extending through the metal layer and to define metal-free regions corresponding to dicing lanes of the device wafer, forming a first adhesive layer over the metal layer, wherein the first adhesive layer is in direct contact with the semiconductor substrate through the plurality of openings, providing a backside support wafer, bonding the device wafer to the backside support wafer through the first adhesive layer, and curing the first adhesive layer to secure the backside support wafer to the device wafer.

Optionally, in the preceding aspect, the method further comprises forming a second adhesive layer over the backside support wafer, wherein bonding the device wafer to the backside support wafer comprises bringing the first adhesive layer into contact with the second adhesive layer, and curing the first adhesive layer and the second adhesive layer to secure the backside support wafer to the device wafer.

Optionally, in any of the preceding aspects, the method further comprises after curing the first adhesive layer to secure the backside support wafer to the device wafer, performing a singulation process to separate a plurality of chips in the device wafer into a plurality of packages, wherein each of the plurality of packages comprises a piece of the backside support wafer.

Optionally, in any of the preceding aspects, the metal layer is recessed from an outer edge of the semiconductor substrate to define an exposed edge portion of the semiconductor substrate, and wherein the exposed edge portion of the semiconductor substrate is in direct contact with the first adhesive layer.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A semiconductor device comprising:
a backside supporting layer having a first thickness;
an adhesive layer over the backside supporting layer;
a metal layer over the adhesive layer, wherein the metal layer functions as a backside connector and comprises a plurality of openings extending through the metal layer;
a semiconductor substrate layer over the metal layer, wherein the semiconductor substrate layer has a second thickness, and wherein the adhesive layer is in direct contact with the semiconductor substrate layer through the plurality of openings; and
a plurality of front side connectors, wherein active circuits in the semiconductor substrate layer are electrically coupled between the plurality of front side connectors and the metal layer.

2. The semiconductor device of claim 1, wherein:
the backside supporting layer is formed of silicon, and wherein the backside supporting layer is free from the active devices; and
the adhesive layer is a dielectric layer formed of a polyimide adhesive material.

3. The semiconductor device of claim 1, further comprising:
a cap layer formed between the adhesive layer and metal layer; and
a passivation layer over the semiconductor substrate layer.

4. The semiconductor device of claim 1, wherein:
the first thickness of the backside supporting layer is greater than the second thickness of the semiconductor substrate layer.

5. The semiconductor device of claim 1, wherein:
the metal layer comprises a plurality of regions arranged in rows and columns, and wherein for openings formed in regions in middle columns, each opening is located at a center portion of a corresponding region.

6. The semiconductor device of claim 1, wherein:
the metal layer comprises a plurality of regions arranged in rows and columns, and wherein for regions in middle columns, each region comprises four openings symmetrically arranged within the region.

7. The semiconductor device of claim 6, wherein:
each region further comprises a center opening located at a central portion of the region;
the center opening and two of the four openings are aligned along a first diagonal of the region; and
the center opening and the other two of the four openings are aligned along a second diagonal of the region.

8. The semiconductor device of claim 6, wherein:
each region further comprises a center opening located at a central portion of the region;
the center opening and two of the four openings are aligned along a first direction through a center of the region; and
the center opening and the other two of the four openings are aligned along a second direction through the center of the region, the second direction being orthogonal to the first direction.

9. The semiconductor device of claim 1, wherein:
the metal layer is recessed from an outer edge of the semiconductor substrate layer such that an edge portion of the semiconductor substrate layer is in direct contact with the adhesive layer.

10. A method comprising:
providing a device wafer having a front side bonded to a substrate, wherein the device wafer comprises a metal layer and a semiconductor substrate;
forming a plurality of openings extending through the metal layer;
providing a backside support wafer;
coating an adhesive material onto a backside of the device wafer to form a first adhesive layer, wherein the first adhesive layer is in direct contact with the semiconductor substrate through the plurality of openings;
coating the adhesive material onto the backside support wafer to form a second adhesive layer;
performing a partial curing process on the first adhesive layer and the second adhesive layer;
bonding the device wafer to the backside support wafer through bringing the first adhesive layer into contact with the second adhesive layer; and
fully curing the first adhesive layer and the second adhesive layer to secure the backside support wafer to the device wafer.

11. The method of claim 10, further comprising:
after bonding the device wafer to the backside support wafer and before performing the full curing process on the adhesive material, de-bonding the substrate from the device wafer; and
after performing the full curing process on the adhesive material, performing a singulation process to separate a plurality of chips in the device wafer into a plurality of packages, wherein each of the plurality of packages comprises a piece of the backside support wafer.

12. The method of claim 11, further comprising:
patterning the metal layer to define metal-free regions aligned with saw dicing lanes of the semiconductor substrate.

13. The method of claim 10, further comprising:
forming the plurality of openings in a plurality of regions arranged in rows and columns, wherein for openings formed in regions in middle columns, each opening is located at a center portion of a corresponding region.

14. The method of claim 10, further comprising:
forming the plurality of openings in a plurality of regions arranged in rows and columns, wherein for regions in middle columns, each region comprises four openings symmetrically arranged within the region.

15. The method of claim 14, further comprising:
forming a center opening at a central portion of the region; and
patterning the metal layer such that the center opening and two of the four openings are aligned along a first diagonal of the region, and the center opening and the other two of the four openings are aligned along a second diagonal of the region.

16. The method of claim 14, further comprising:
forming a center opening at a central portion of the region; and
patterning the metal layer such that the center opening and two of the four openings are aligned along a first direction through the center of the region, and the center opening and the other two of the four openings are aligned along a second direction through the center of the region, wherein the second direction is orthogonal to the first direction.

17. A method comprising:
providing a device wafer comprising a semiconductor substrate and a metal layer disposed over the semiconductor substrate;
patterning the metal layer to form a plurality of openings extending through the metal layer and to define metal-free regions corresponding to dicing lanes of the device wafer;
forming a first adhesive layer over the metal layer, wherein the first adhesive layer is in direct contact with the semiconductor substrate through the plurality of openings;
providing a backside support wafer;
bonding the device wafer to the backside support wafer through the first adhesive layer; and
curing the first adhesive layer to secure the backside support wafer to the device wafer.

18. The method of claim 17, further comprising:
forming a second adhesive layer over the backside support wafer, wherein bonding the device wafer to the backside support wafer comprises bringing the first adhesive layer into contact with the second adhesive layer; and
curing the first adhesive layer and the second adhesive layer to secure the backside support wafer to the device wafer.

19. The method of claim 17, further comprising:
after curing the first adhesive layer to secure the backside support wafer to the device wafer, performing a singulation process to separate a plurality of chips in the device wafer into a plurality of packages, wherein each of the plurality of packages comprises a piece of the backside support wafer.

20. The method of claim 19, wherein:
the metal layer is recessed from an outer edge of the semiconductor substrate to define an exposed edge portion of the semiconductor substrate, and wherein the exposed edge portion of the semiconductor substrate is in direct contact with the first adhesive layer.
